(19) United States
(12) Patent Application Publication
(10) Pub. No.: US 2026/0026587 A1
(43) Pub. Date: Jan. 29, 2026

(54) MULTI-RECEPTACLE CARRYING AND STORAGE ARTICLE

(71) Applicant: Kyndel King, Atlanta, GA (US)

(72) Inventor: Kyndel King, Atlanta, GA (US)

(21) Appl. No.: 19/278,713

(22) Filed: Jul. 23, 2025

Related U.S. Application Data
(60) Provisional application No. 63/674,787, filed on Jul. 23, 2024.

(51) Int. Cl. A45C 11/00; A45C 3/00; A45C 13/10; A45C 13/30; A45F 3/02; A45F 3/04; H05K 9/00

(52) U.S. Cl. CPC A45C 11/002; A45C 3/001; A45C 13/30; A45F 3/02; H05K 9/0043; A45C 13/1076; A45F 3/04

(57) ABSTRACT

A multi-receptacle carrying and storage article comprising at least two receptacles having different orientations and form factors where at least one receptacle comprises signal blocking technology and at least one receptacle does not include signal blocking technology and a method of using the multi-receptacle carrying and storage article.

### CROSS REFERENCE TO RELATED APPLICATION

This application claims the benefit of U.S. Patent Application Ser. No. 63/674,787, which was filed on Jul. 23, 2024, and is incorporated herein by reference in its entirety.

### TECHNICAL FIELD

This disclosure relates to implementations of a multi-receptacle carrying and storage article.

### BACKGROUND

Carrying bags having pouches fixedly lined with signal blocking material exists. However, these bags lack flexibility because the pouches will always block wireless signals. However, it is desirable to have the option to block or transmit/receive wireless signals. Furthermore, a carry and storage article with a plurality of storage options and plurality of carrying options do not exist.

### BRIEF DESCRIPTION OF THE DRAWINGS

FIGS. 1A, 1B, 2-3, 9A-9B, and 10 illustrate example implementations of a multi-receptacle carrying and storage article according to the present disclosure.

FIG. 4 illustrates an example implementation of a receptacle having signal blocking material according to the present disclosure.

FIG. 5 illustrates an example implementation of signal blocking material according to the present disclosure.

FIG. 6 illustrates an example implementation of a buckle according to the present disclosure.

FIG. 7 illustrates an example implementation of a configuration of multiple connected receptacles according to the present disclosure.

FIGS. 8A and 8B illustrate example implementations of a back of a multi-receptacle carrying and storage article according to the present disclosure.

### DETAILED DESCRIPTION

The present disclosure relates to a multi-receptacle carrying and storage article. The multi-receptacle carrying and storage article comprises multiple receptacles with different orientations, different form factors, and different abilities to block wireless signals (e.g., wireless signals used for cellular network, WI-FI, BLUETOOTH, and other signals) to enhance digital privacy and personal identity.

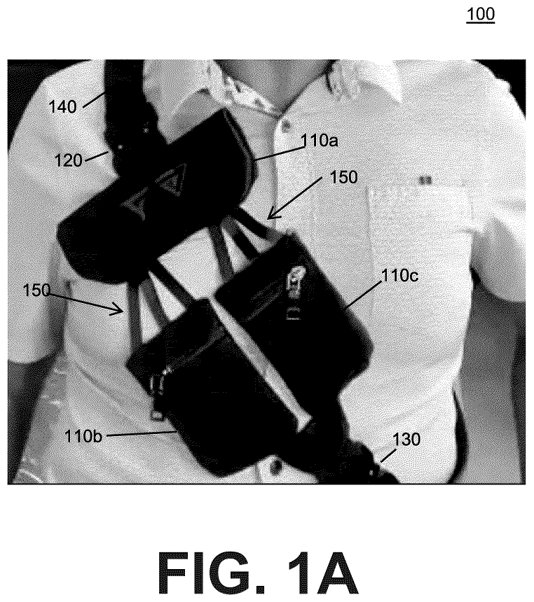

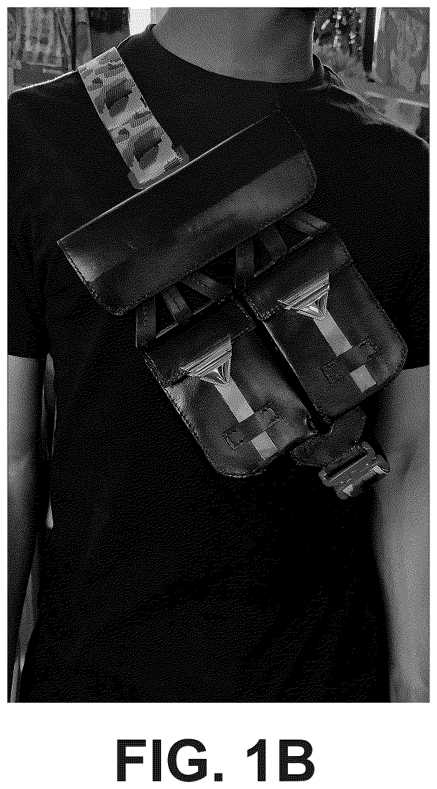

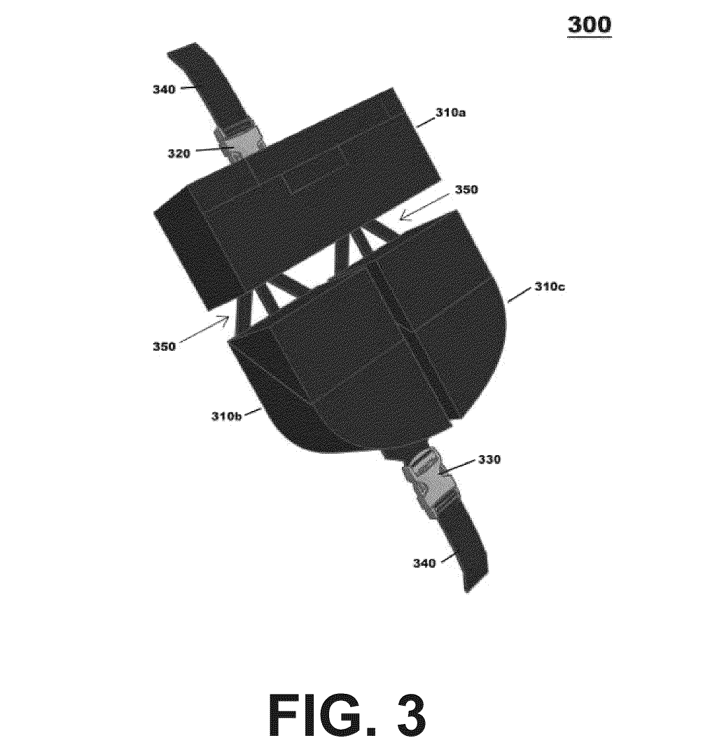

FIGS. 1-3 illustrate example implementations of a multi-receptacle carrying and storage article 100, 200, 300 according to the present disclosure.

In some implementations, the multi-receptacle carrying and storage article may comprise at least two receptacles with different orientations. For example, as shown in FIGS. 1-3, a first receptacle 110a, 210a, 310a can be elongated in a first direction (e.g., horizontally) and a second receptacle 110b, 210b, 310b, may be elongated in a second direction (e.g., vertical). In some implementations, the multi-receptacle carrying and storage article may comprise a third receptacle 110c, 210c, 310c. In some implementations, the multi-receptacle carrying and storage article may comprise more than three receptacles. In some implementations, the multi-receptacle carrying and storage article may comprise one receptacle.

In some implementations, the multi-receptacle carrying and storage article may comprise at least two receptacles with different sizes and/or shapes. For example, a first receptacle 110a, 210a, 310a may be sized and shaped to hold a cellular phone and a second receptacle 110b, 210b, 310b may be smaller or larger than the first receptacle or shaped differently than the first receptacle.

One or more of the receptacles may be used to store a variety of items such as keys, a pen, a comb, lip balm, glasses, wallet, passport, money clip, credit card(s), identification card, licenses, aerosol self-defense spray. In some implementations, one or more of the receptacles may be used to store small electronic devices such as a cellular phone, ear-pods, AIRPODS, a key fob, or any portable electronic device including portable electronic devices capable of wireless communication.

In some implementations, the multi-receptacle carrying and storage article may comprise at least two receptacles with different abilities to block wireless signals.

For example, a first receptacle (e.g., 110a, 210a, 310a) may house a signal blocking material, such as a Faraday fabric/material, to be used to prevent the transmission of wireless signals into or out of the receptacle. But, in some implementations, a second receptacle (110b, 210b, 310b) may not contain any signal blocking material/technology such that the receptacle does not prevent the transmission of wireless signals into or out of the receptacle. In this way, items may be housed based on the level of privacy desired. For example, a cellular phone, credit card, or building access card may be housed in the first receptacle for protection while other less sensitive items may be stored in the second receptacle.

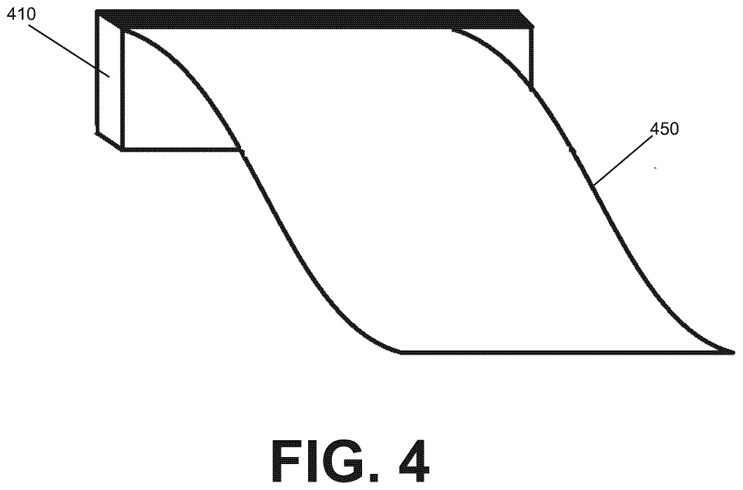

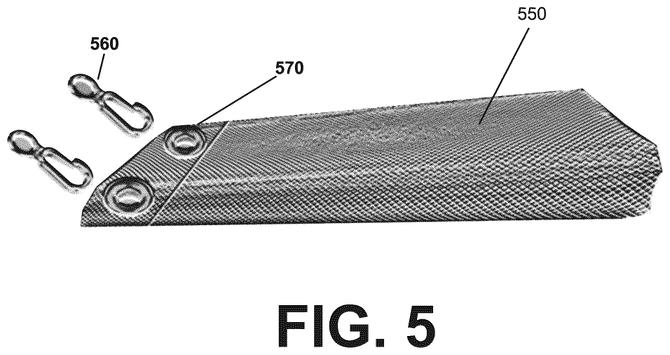

FIG. 4 illustrates an example implementation of a receptacle having signal blocking material 450 according to the present disclosure. FIG. 5 illustrates an example implementation of signal blocking material 550 according to the present disclosure.

In some implementations, as shown in FIG. 4, a receptacle 410 housing a signal blocking material 450 may comprise an elongated piece of signal blocking material 450 where one end of the signal blocking material is attached to a portion of the inner surface of the receptacle 410 and the other end of the signal blocking material is not attached to anything and able to move freely. In this way, the signal blocking material can be wrapped around an item to be stored in the receptacle 410 and then the wrapped item can be stored in the receptacle 410. In this way, the first receptacle 410 is not fixedly lined with a signal blocking material; instead, the signal blocking material 450 is attached to the receptacle on one end. In this way, in some implementations, multiple items can be placed in the receptable 410 with varying levels of protection depending on whether the item is wrapped in the signal blocking material. Furthermore, smaller items care be stored more snugly because they are wrapped in the signal blocking material instead of in the open enclosure of the receptacle.

In some implementations, as shown in FIG. 5, the signal blocking material 550 may be in the form of a pouch. In some implementations, the signal blocking material 450, 550 may be detachable from the receptacle for use of the signal blocking material outside of the receptacle. For example, in some implementations, one or more clips 560 may be secured to the inner surface of the receptacle and the signal blocking material 550 may be removably attached to the receptacle by inserting the one or more clips 560 through opening 570 in the signal blocking material 550. In some implementations, any suitable attachment device can be used to removable attach the signal blocking material to a portion of the inner surface of the receptacle.

In some implementations, the length of the signal blocking material 450 or pouch 550 is or is about 6.5 inches. In some implementations, the length of the signal blocking material 450 or pouch 550 is greater than 6.5 inches. In some implementations, the length of the signal blocking material 450 or pouch 550 is less than 6.5 inches.

In some implementations, the width of the signal blocking material 450 or pouch 550 is or is about 3.5 inches. In some implementations, the width of the signal blocking material 450 or pouch 550 is greater than 3.5 inches. In some implementations, the width of the signal blocking material 450 or pouch 550 is less than 3.5 inches.

In some implementations, the signal blocking material comprises copper. In some implementations, the signal blocking material comprises a copper and nickel composition. In some implementations, the signal blocking material comprises a polyester fiber, metallic copper, and metallic nickel composition. In some implementations, the signal blocking material is configured to block wireless signals. In some implementations, the signal blocking material is configured to block radio frequency (RF) signals such as RF signals used for cellular communication, wireless local area network communication, WI-FI, BLUETOOTH, Global Positioning System (GPS), Radio-Frequency Identification (RFID), and Near Field Communication (NFC). In some implementations, the signal blocking material is configured to block RF signals and radio signals from the low MHz to 40 GHZ. In some implementations, the signal blocking material is configured to block RF signals greater than 40 GHZ. In some implementations, any signal suitable blocking material can be used to shield electronic devices from RF signals, electromagnetic pulses (EMPs), electromagnetic fields (EMFs), and/or electromagnetic interference (EMI) to provide data security thereby enhancing digital privacy and personal identity.

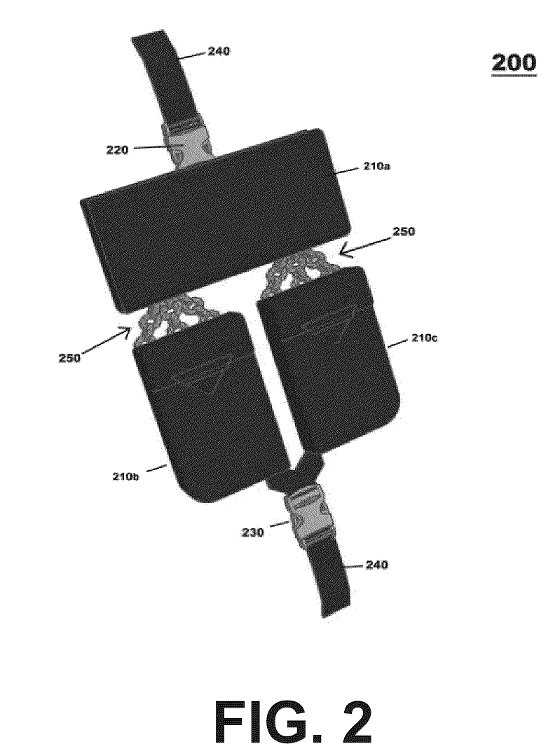

As shown in FIG. 1A, in some implementations, the multi-receptacle carrying and storage article may comprise an adjustable strap 140 having buckles 120, 130 on opposite ends. FIG. 2 also shows a multi-receptacle carrying and storage article comprising an adjustable strap 240 having buckles 220, 230 on opposite ends.

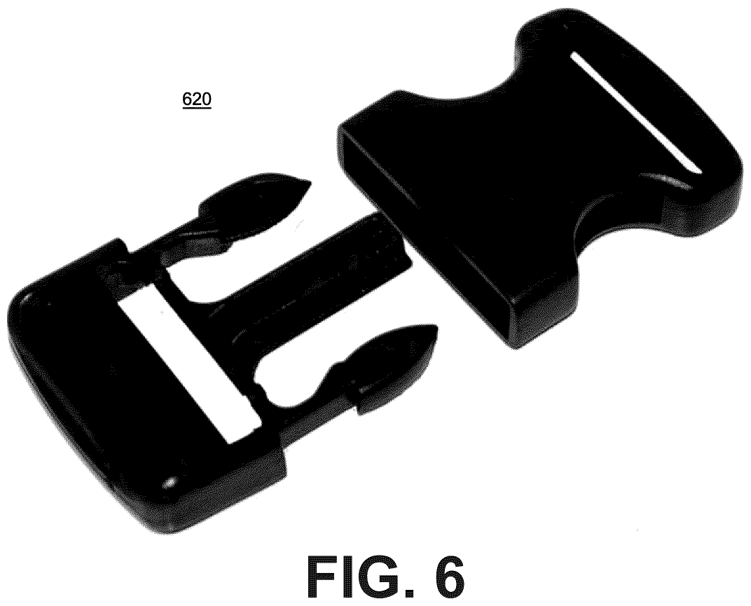

In some implementations, the multi-receptacle carrying and storage article 100, 200, 300 comprises a configuration 700 of multiple connected receptacles having mating buckles to the buckles attached to the strap 140. The mating buckles of the configuration 700 of multiple connected receptacles are configured to releasably attach to the buckles 120, 130 on the adjustable strap 140 to connect the strap to the receptacles for wearing the multi-receptacle carrying and storage article on a person (e.g. as shown in FIGS. 1A and 1B). FIG. 6 illustrates an example implementation of mating buckles 620 according to the present disclosure.

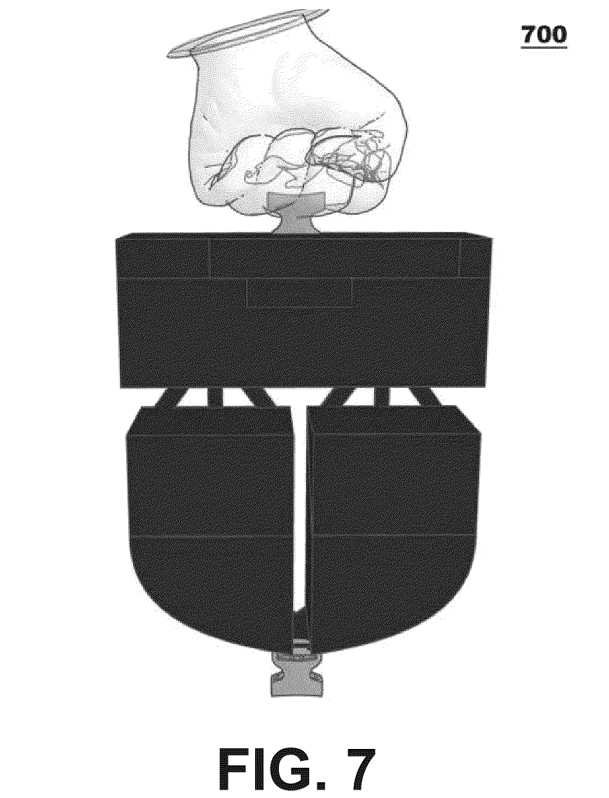

In some implementations, the configuration 700 of multiple connected receptacles may be hand carried without use of the strap 140 as shown in FIG. 7.

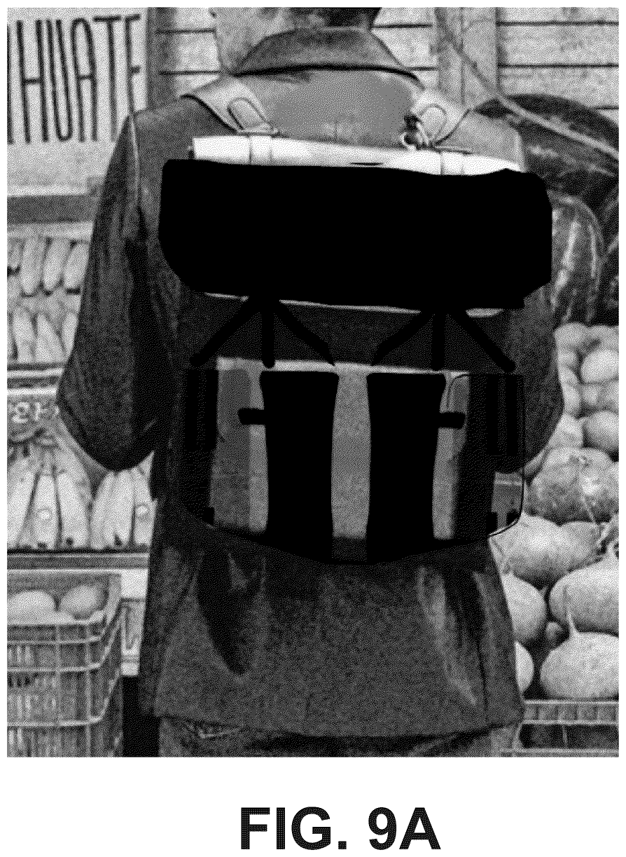

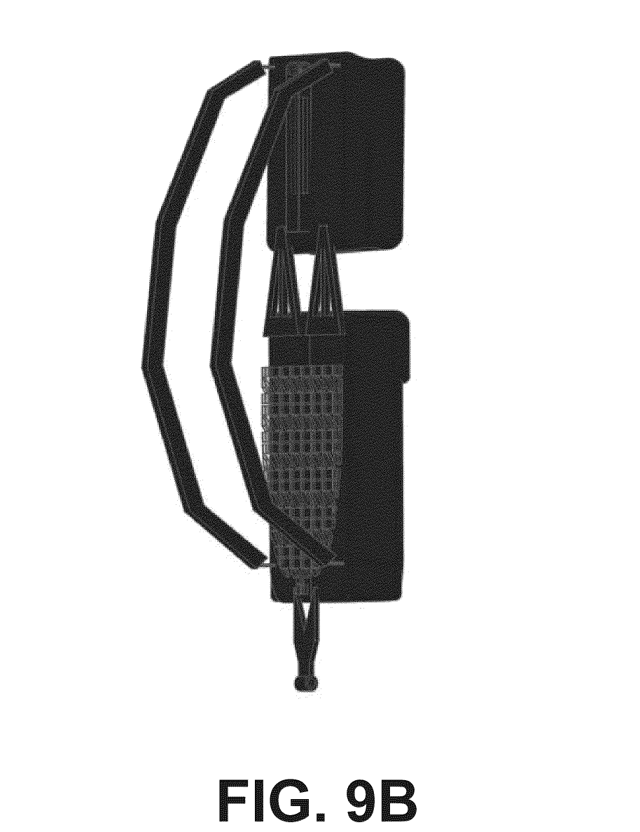

In some implementations, as shown in FIGS. 9A and 9B, the multi-receptacle carrying and storage article may be configured to be worn as a backpack.

In some implementations, the adjustable strap 140 is sized to extend across a user's back and extend toward the front of the user's body as shown in FIGS. 1A and 1B. In some implementations, the adjustable strap is about 43.5 inches.

In some implementations, the adjustable strap 140 may be adjusted such that the multi-receptacle carrying and storage article may be worn around the waist in similar fashion as a utility or tool belt, or worn over the shoulder, or worn over one's hip area.

In some implementations, the strap 140 may be attached to the configuration 700 of multiple connected receptacles using a hook and loop attachment such as Velcro, zippers, snaps, buttons, magnets, loops (e.g., similar to belt loops, for example, on the back of receptacle 110a), or other suitable attachment or fastening technology existing or developed in the future.

In some implementations, the strap is fixedly attached (e.g., sewn) to the configuration of multiple connected receptacles.

In some implementations, one or more of the receptacles are made from any flexible textile or textile-like material. In some implementations, one or more of the receptacles may be made from cotton, nylon, leather, or the like. In some implementations, one or more of the receptacles may be made from hard-case materials. In some implementations, one or more of the receptacles may be made from wood, metals, polyurethane material, carbons, or the like.

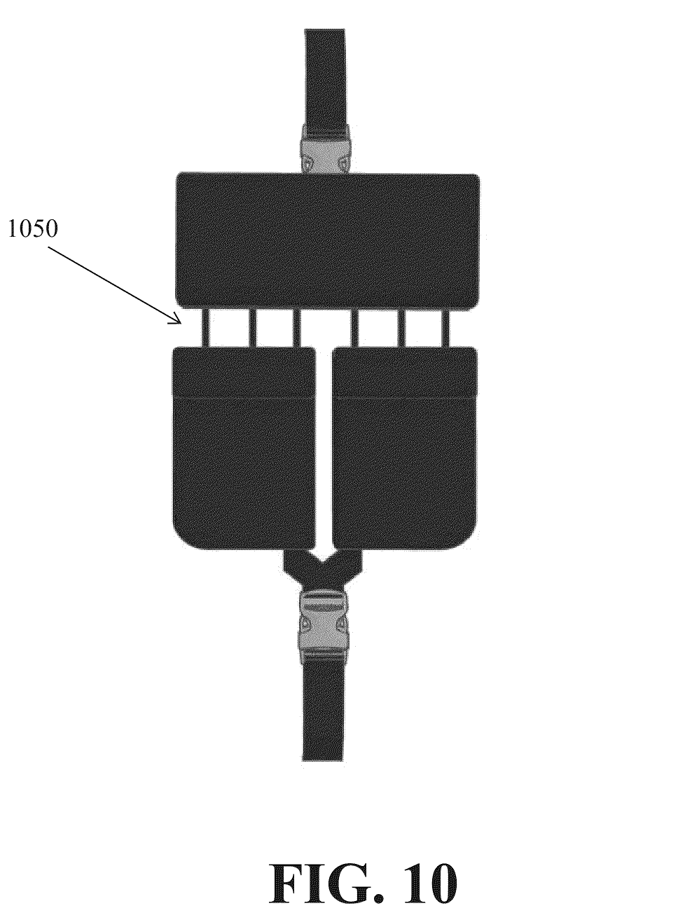

As shown in the figures, in some implementations, straps 150, 250, 350 are used to connect one receptacle to another receptacle. As shown in the figures, the pyramid straps 150, 250, 350 comprise a plurality of straps (e.g., three straps) arranged in a pyramid or triangular configuration as shown in the figures to attach two receptacles. In some implementation, the straps 1050 may be arranged in a rectangular configuration as shown in FIG. 10. In some implementation, the straps used to connect one receptacle to another receptacle may be arranged in any suitable configuration.

In some implementations, the receptacles are arranged in a pyramid or triangular configuration. As shown in the figures, one or more receptacles are attached to a top receptacle where the one or more bottom receptacles are attached along the length of the top receptacle to balance the configuration. In some implementations, the pyramid configuration of the receptacles along with the pyramid straps create a very stable carrying and storage article.

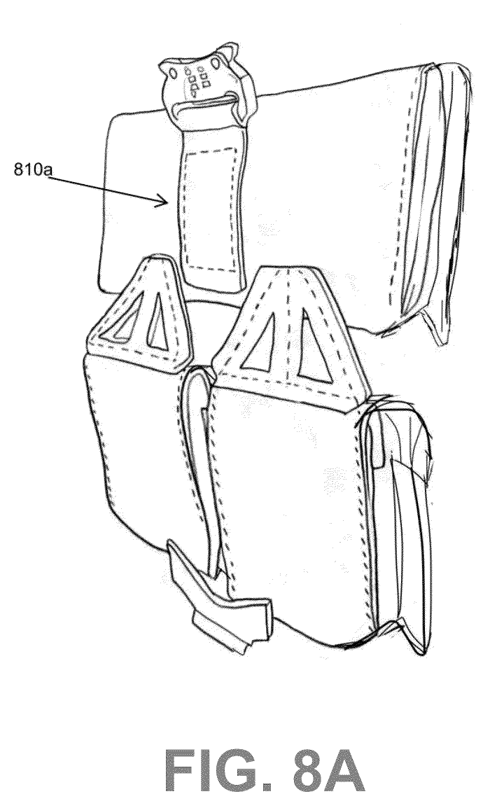

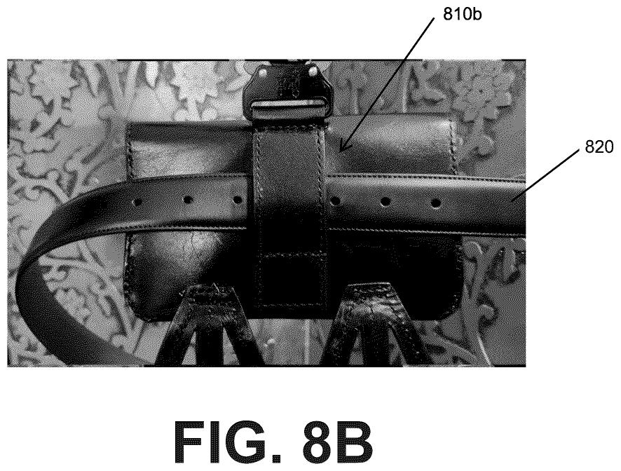

FIGS. 8A and 8B illustrate example implementations of a back of a multi-receptacle carrying and storage article according to the present disclosure. In some implementations, the multi-receptacle carrying and storage article may comprise a belt loop 810a, 810b for insertion of a belt 820 such that the multi-receptacle carrying and storage article may be worn around the waist.

The figures, including photographs and drawings, comprised herewith may represent one or more implementations of the present disclosure.

Details shown in the figures, such as dimensions, descriptions, etc., are exemplary, and there may be implementations of other suitable details according to the present disclosure.

Reference throughout this specification to “an embodiment” or “implementation” or words of similar import means that a particular described feature, structure, or characteristic is comprised in at least one embodiment of the present invention. Thus, the phrase “in some implementations” or a phrase of similar import in various places throughout this specification does not necessarily refer to the same embodiment.

Many modifications and other embodiments of the inventions set forth herein will come to mind to one skilled in the art to which these inventions pertain having the benefit of the teachings presented in the foregoing descriptions and the associated drawings.

The described features, structures, or characteristics may be combined in any suitable manner in one or more embodiments. In the above description, numerous specific details are provided for a thorough understanding of embodiments of the invention. One skilled in the relevant art will recognize, however, that embodiments of the invention can be practiced without one or more of the specific details, or with other methods, components, materials, etc. In other instances, well-known structures, materials, or operations may not be shown or described in detail.

While operations may be depicted in the drawings in a particular order, this should not be understood as requiring that such operations be performed in the particular order shown or in sequential order, or that all illustrated operations be performed, to achieve desirable results.

1. A multi-receptacle carrying and storage article comprising:
at least two receptacles that are separate where the at least two receptacles have separate outer surfaces forming respective enclosures wherein:
the first receptacle has a first orientation and a first form factor and the second receptacle has a second orientation and second form factor where the first orientation and the second orientation are different and the first form factor and the second form factor are different;
the first receptacle comprises signal blocking technology so that when a portable electronic device capable of wireless communication is placed in the enclosure of the first receptable, wireless signals to and from the portable electronic device are blocked;
the second receptacle does not comprise signal blocking technology so that when a portable electronic device capable of wireless communication is placed in the enclosure of the second receptable, wireless signals to and from the portable electronic device are not blocked; and
the at least two receptacles are fixedly connected to each other and releasable attached to an adjustable strap for carrying the receptacle on a person using the strap.

2. The multi-receptacle carrying and storage article of claim 1 wherein at least one of the at least two receptacles is elongated in a first direction and at least one of the at least two receptacles is elongated in a second direction wherein the first and second direction are different.

3. The multi-receptacle carrying and storage article of claim 1 wherein the first receptacle is sized to hold a cellular phone.

4. The multi-receptacle carrying and storage article of claim 1 wherein the first receptacle comprises an elongated piece of signal blocking material extending lengthwise from a first side to a second side where at least a portion of the first side of the signal blocking material is attached to a portion of the inner surface of the first receptacle and the second side of the signal blocking material is not attached to anything and able to move freely (i.e., free floating).

5. The multi-receptacle carrying and storage article of claim 4 wherein the signal blocking material is a Faraday material.

6. The multi-receptacle carrying and storage article of claim 1 wherein the first receptacle comprises an elongated piece of signal blocking material in the form of a pouch wherein the pouch extends lengthwise from a first side to a second side and wherein at least a portion of the first side of the signal blocking material is removably attached to a portion of the inner surface of the first receptacle.

7. The multi-receptacle carrying and storage article of claim 1 further comprising a third receptacle that is separate for the at least two receptacles where the third receptacle has a separate outer surface forming a respective enclosure.

8. The multi-receptacle carrying and storage article of claim 1 wherein the at least two receptacles are fixedly connected to each other with a plurality of straps.

9. A receptacle comprising:
a material forming an enclosure configured to receive and house a portable electronic device capable of wireless communication wherein the inner surface of the enclosure is not fixedly lined with any single blocking material; and
an elongated piece of signal blocking material extending lengthwise from a first side to a second side where at least a portion of the first side of the signal blocking material is attached to a portion of the inner surface of the receptacle and the second side of the signal blocking material is not attached to anything and able to move freely.

10. The receptacle of claim 9 wherein the elongated piece of signal blocking material is in the form of a pouch and wherein at least a portion of the first side of the signal blocking material is removably attached to a portion of the inner surface of the first receptacle.

11. The receptacle of claim 9 wherein the signal blocking material is a Faraday material.

12. The receptacle of claim 10 wherein the signal blocking material is a Faraday material.

13. A method of using the receptacle of claim 9 comprising:
wrapping a portion of the elongated piece of the signal blocking material around a first portable electronic device capable of wireless communication sufficient for the signal blocking material to block signals to and from the first portable electronic device and placing the first portable electronic device inside the enclosure.

14. The method of claim 13 further comprising placing a second portable electronic device capable of wireless communication inside the enclosure without wrapping a portion of the elongated piece of the signal blocking material around the second portable electronic device so that wireless signals maybe received by and transmitted from the second portable electronic device.

15. A method of using the receptacle of claim 10 comprising:
placing a first portable electronic device capable of wireless communication inside the pouch, folding the signal blocking material from the fee end, and placing the first portable electronic device inside the enclosure.

16. The method of claim 13 wherein the first portable electronic device is a cellular phone.

17. A multi-receptacle carrying and storage article comprising:
at least two receptacles that are separate where the at least two receptacles have separate outer surfaces forming respective enclosures wherein:
the inner surface of neither of the enclosures is fixedly lined with a signal blocking material;
at least one of the at least two receptacles comprises an elongated piece of signal blocking material extending lengthwise from a first side to a second side where at least a portion of the first side of the signal blocking material is attached to a portion of the inner surface of the at least one of the at least two receptacles and the second side of the signal blocking material is not attached to anything and able to move freely so that when a portable electronic device capable of wireless communication is wrapped with the signal blocking material and placed in the enclosure of the at least one of the at least two receptacles, wireless signals to and from the portable electronic device are blocked; and
the at least two receptacles are connected to each other and releasable attached to an adjustable strap for carrying the receptacle on a person using the strap.

18. The multi-receptacle carrying and storage article of claim 17 wherein the elongated piece of signal blocking material is in the form of a pouch and wherein at least a portion of the first side of the signal blocking material is removably attached to a portion of the inner surface of the first receptacle.

19. A method of using the multi-receptacle carrying and storage article of claim 17 comprising:
wrapping a portion of the elongated piece of the signal blocking material around a first portable electronic device sufficient for the signal blocking material to block signals to and from the first portable electronic device and placing the first portable electronic device inside the enclosure of the at least one of the at least two receptacles.

20. A method of using the multi-receptacle carrying and storage article of claim 18 comprising:
placing a first portable electronic device capable of wireless communication inside the pouch, folding the signal blocking material from the fee end, and placing the first portable electronic device inside the enclosure.
